(19) United States
(12) Patent Application Publication
(10) Pub. No.: US 2005/0008171 A1
(43) Pub. Date: Jan. 13, 2005

(54) Audio data processing device, audio data processing method, program for the same, and recording medium with the program recorded therein

(75) Inventors: Shintaro Hosoi, Tokorozawa-shi (JP); Hiroyuki Hamada, Tokorozawa-shi (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: PIONEER CORPORATION, Tokyo (JP)

(21) Appl. No.: 10/876,593

(22) Filed: Jun. 28, 2004

(30) Foreign Application Priority Data
Jul. 4, 2003 (JP) 2003-192103

(51) Int. Cl. H03G 5/00; H03G 1/00

(52) U.S. Cl. 381/98; 381/97

(57) ABSTRACT

A controller (710) having recognized an output request for bass mood sounds in response to an input operation by the audience sets a prespecified low-pass filter (830) by switching a filter selecting section (840) and a bass sound processing switching section (870). The audio data inputted from input terminals (631) respectively is subjected to adjustment of the output level as well as to the effect processing, and then is passed through the prespecified low-pass filter (830) to adjust the output, and then is outputted from output terminals (638) corresponding to speakers (230) for bass mood sounds. Audio data outputted from other speakers (230) is subjected to output adjustment, and is subjected to the delay processing according to a delay time computed by the controller through an operational expression approximated with a quadratic expression for a cut-off frequency in the low-pass filter (830) to be outputted from the output terminals (638) corresponding to the speakers (230).

### BACKGROUND OF THE INVENTION

1. Field of the Invention

The present invention relates to an audio data processing device, an audio data processing method, a program for the same, and a recording medium for the program recorded therein.

2. Description of Related Art

There has been known a reproduction system for reproducing multi-channel audio data using a plurality of speakers. In this reproduction system, for instance, image data is displayed on a monitor with a plurality of speakers arranged around the audience, and audio data is reproduced from around the audience. The audio data reproduced in this system is recorded, for instance, in a package medium such as a DVD (Digital Versatile Disc), or is distributed through a network such as the Internet. The audio data is for sounds produced with a musical instrument or for those produced by an electronic musical instrument generally called synthesizer, and the data is processed by an audio data processing device and is recorded in a package medium or distributed through a network.

In relation to the audio data processing device based on the conventional technology, there has been known the configuration in which bass mood sounds to be reproduced by a speaker for bass mood sounds are generated. This audio data processing device fetches, in addition to audio data of independent mood sounds, bass components of the audio data provided through a main channel such as a center channel or a front channel and outputted for reproduction by other speakers such as center speaker, right and left front speakers, or right and light surround speakers by making use of a law-pass filter. The fetched audio data is generated as audio data for bass mood sounds to be provided through a bass mood sound channel.

However, in the conventional type of audio data processing device as described above, when bass sound channel is generated from a main channel such as a center channel or right and left front channel by using a low-pass filter, there is the possibility that delay occurs due to characteristics of the low-pass filter. When channels from the speakers are reproduced by the reproduction system, a time difference may occur between a timing for reproducing and outputting sounds from the main channel and that from the bass mood sound channel because of the delay. Because of this time delay, a phase difference between the main channel and the bass mood sound channel becomes larger, which may disable provision of sufficient and comfortable bass mood sounds, and also the sound quality may be degraded due to the timing mismatch, which is one of the defects of the conventional technology.

### SUMMARY OF THE INVENTION

A main object of the present invention is to provide, for solving the problems in the conventional technology as described above, an audio data processing device capable of adequately outputting bass mood sounds, an audio data processing method, a program for the same, and a recording medium with the program recorded therein.

An audio data processing device according to an aspect of the present invention is an audio data processing device for processing audio data so that the audio data can be reproduced from a plurality of speakers, and comprises an audio data fetching section for fetching the audio data; a delay processor for delaying the audio data; a filter only allowing passage of audio data having a prespecified frequency outputted from the prespecified speakers; and a control section for subjecting the audio data reproduced by said speakers without passing through said filter to the delay processing in the delay processor to delay the audio data by the period of time corresponding to the delay generated when said audio data passes through said filter.

The audio data processing device according to another aspect of the present invention is an audio data processing device for processing audio data so that the audio data can be reproduced from a plurality of speakers, and comprises an audio data fetching section for fetching the audio data; a storage section for storing therein the fetched audio data together with the timing information concerning the timing when the audio data is fetched; a filter allowing for passage of data having a prespecified frequency among the audio data outputted from the prespecified speakers, and a control section for fetching a synchronization signal corresponding to the timing when the audio data is fetched, reading out based on the synchronization signal the audio data stored in the storage section and correlated to the timing information specifying an earlier timing corresponding to a delay generated when the audio data passes through the filter and having the audio data passed through the filter so that the audio data can be outputted to be reproduced from said speakers, and also having the audio data stored in the storage section and correlated to said timing information specifying a timing corresponding to the synchronization signal outputted without being passed through the filter so that the audio data can be outputted to be reproduced by said speakers.

An audio data processing method according to still another aspect of the present invention is a method of processing audio data so that the audio data can be reproduced from a plurality of speakers, and the method comprises the steps of: having the audio data outputted from the prespecified speakers passed through a filter allowing passage of audio data having a prespecified frequency; and subjecting the audio data not passing through the filter and reproduced by the speakers to the replay processing for delaying the audio data by the delay generated when the audio data passes through the filter.

An audio data processing method according to further aspect of the present invention is a method of processing audio data so that the audio data can be reproduced from a plurality of speakers, and the method comprises the steps of: fetching the audio data and also fetching a synchronization signal corresponding to the timing when the audio data is fetched; storing the fetched audio data together with timing information concerning the timing when the audio data is fetched based on the synchronization signal; and reading out, based on the synchronization signal, the audio data correlated to the timing information for an earlier timing corresponding to the delay generated when the audio data outputted from the speakers is passed through a filter allowing passage of the audio data having a prespecified frequency to pass the audio data through the filter so that the audio data can be outputted to be reproduced from the speakers, and also reading out the audio data correlated to said timing information for a timing corresponding to the synchronization signal and outputting the audio data so that the audio data can be reproduced from the speakers without being passed through the filter.

An audio data processing program according to still further aspect the present invention makes the computing section execute the audio data processing method described above.

A recording medium with the program recorded therein according to still further aspect of the present invention has the audio data processing program recorded therein so that the audio data processing programs can be read out by the computing section.

### BRIEF DESCRIPTION OF THE DRAWINGS

FIG. 1 is a block diagram showing a general configuration of a reproducing device related to an embodiment of the present invention;

FIG. 2 is a block diagram showing a general configuration of a program for a digital signal processing section in the embodiment;

FIG. 3 is a block diagram showing a general configuration of a mixing effect section in the embodiment;

FIG. 4 is a graph showing a difference between the cases with and without the delaying processing in the relation to the group delay characteristic and frequencies in the embodiment;

FIG. 5 is a graph showing a relation between an impulse response and a delay time in the embodiment; and

FIG. 6 is a graph showing a difference between the cases with and without the delaying processing in the relation to the frequency amplitude characteristic and frequencies in the embodiment.

### DETAILED DESCRIPTION OF PREFERRED EMBODIMENT(S)

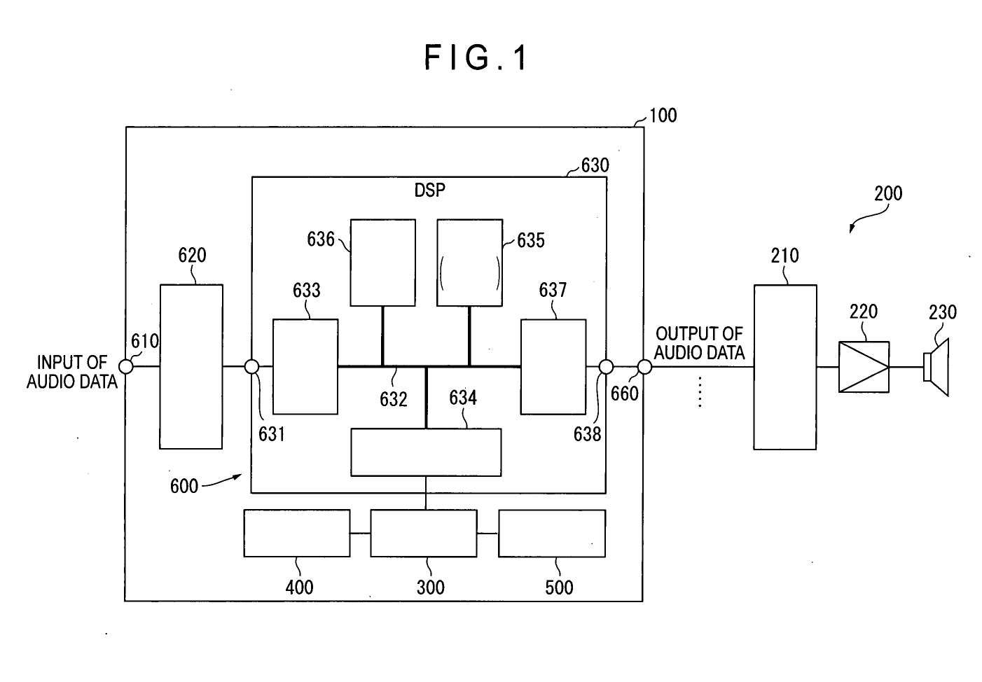

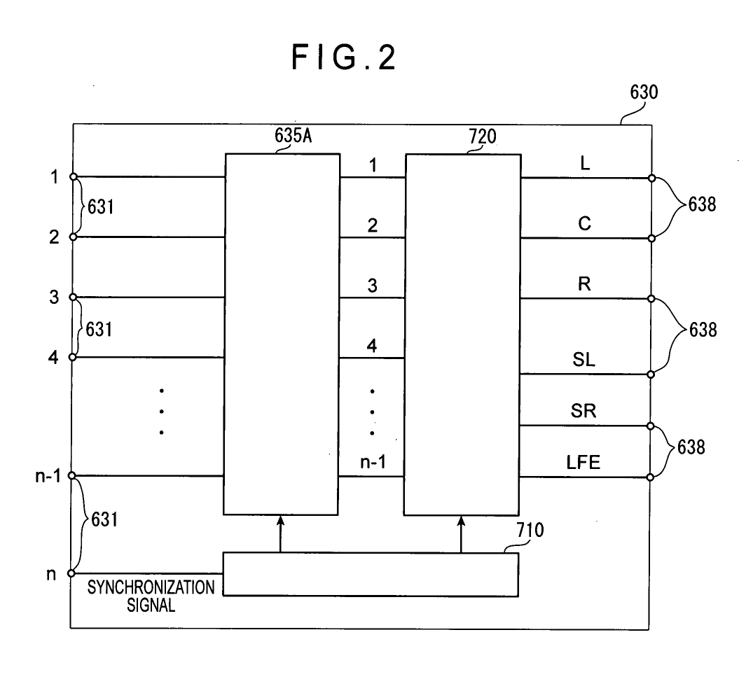

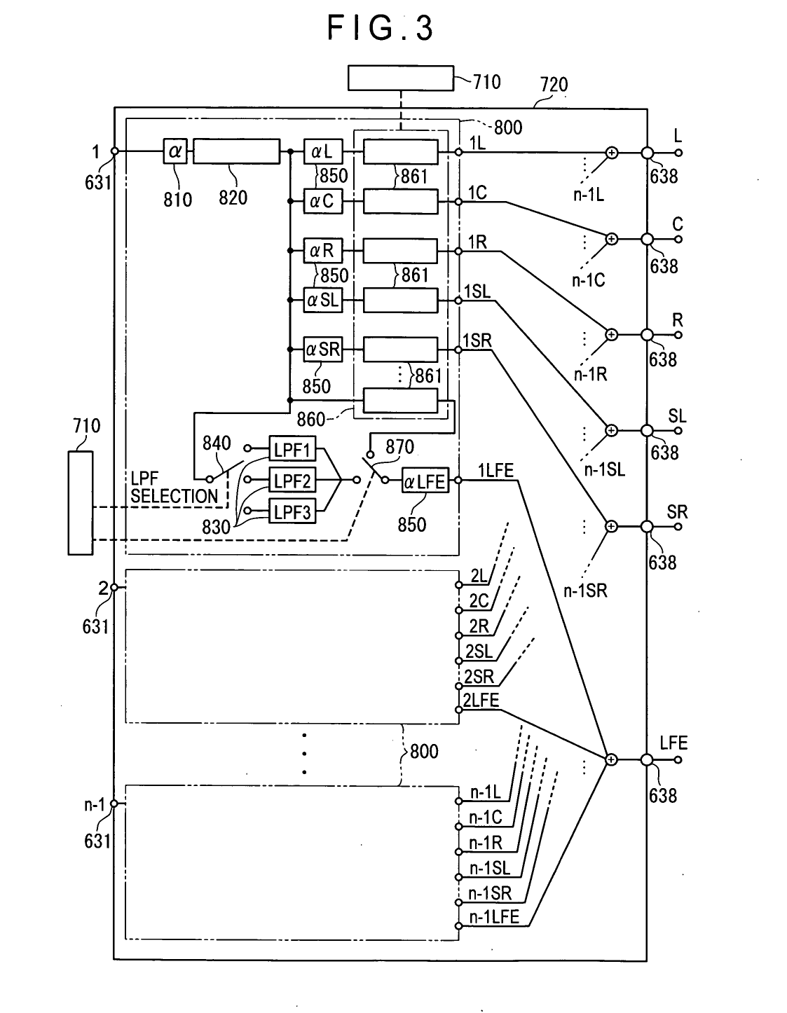

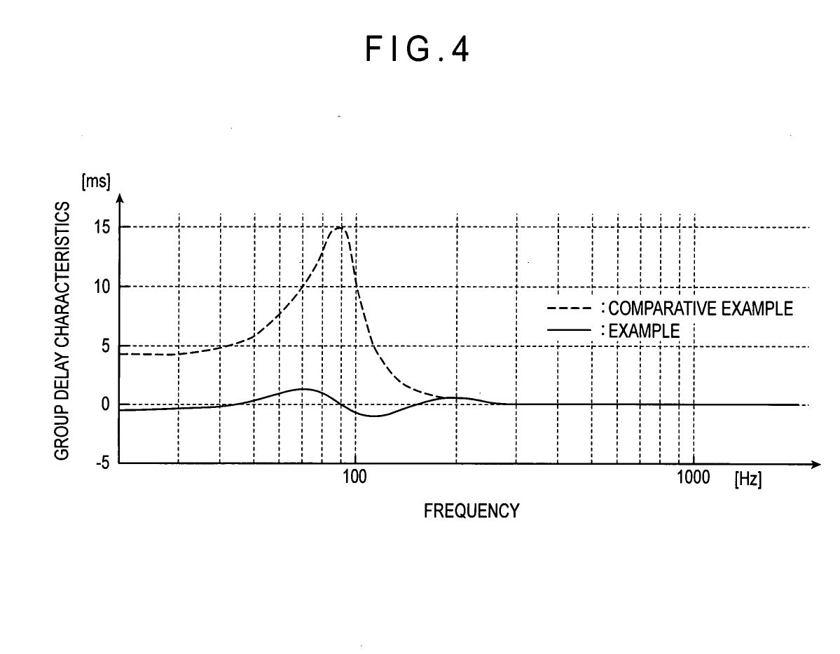

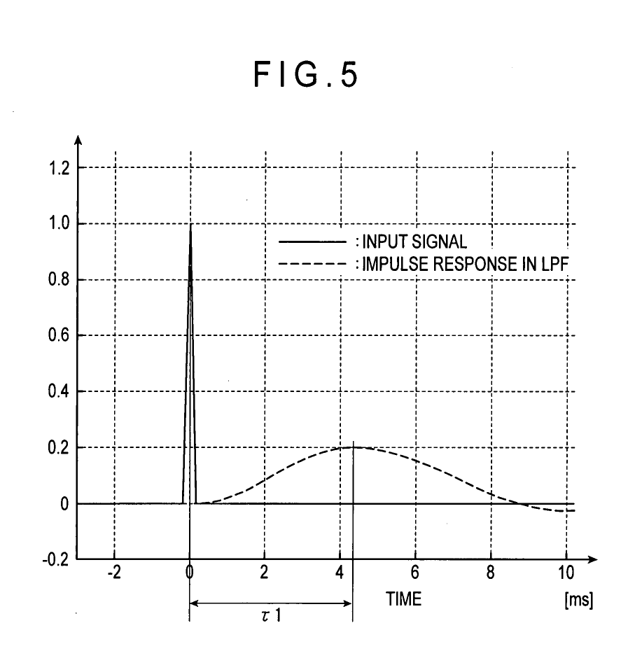

A reproducing device according to one embodiment of the present invention is described below with reference to the related drawings. It is to be noted that, although the configuration in which audio data is outputted for reproduction is described in this embodiment, the present invention is not limited to this configuration, and the configuration is allowable in which, together with audio data, image data is processed and outputted for reproduction, and in which a so-called mixer is used for processing and outputting data for reproduction. Further, the configuration is described below in which a speaker reproduces and outputs audio data, but the present invention can also be applied to the configuration in which the processed audio data is recorded in a recording medium such as an optical disk and a magnetic disk including a DVD (Digital Versatile Disc) and a HD (Hard Disk), a magnetic tape, an audio track of a film, memory, or the like, or the configuration in which the processed audio data is distributed via a network. FIG. 1 is a block diagram showing general configuration of a reproducing device. FIG. 2 is a block diagram showing general configuration of a digital signal processing section in the reproducing device as a program. FIG. 3 is a block diagram showing general configuration of a mixing effect section. FIG. 4 is a graph showing a difference a difference between the cases with and without the delaying processing in the relation to the group delay characteristic and frequencies. FIG. 5 is a graph showing a difference between the cases with and without the delaying processing in the relation to the frequency amplitude characteristic and frequencies.

[Configuration of the Reproducing Device]

In FIG. 1, the reference numeral 100 indicates a reproducing device, and the reproducing device 100 processes audio data and image data so that the audience can watch and listen to them. To the reproducing device 100 are connected to a plurality of outputting sections 200 for reproducing the processed audio date, namely outputting the data as voice.

Respective outputting sections 200 reproduce and output various audio data outputted from the reproducing device 100. These outputting sections 200 each comprise a DAC (Digital-Analog Converter) 210, an amplifier 220, and a speaker 230, and in this configuration, a plurality (for example, 6 pairs) of output sections are provided.

Description of this embodiment assumes the configuration of, for example, the so-called 5.1 channels (5.1 ch) as the speakers 230 of a plurality of output sections 200 including a center speaker 230C positioned at reference audio position, namely, substantially at the front of the audience listening to the reproduced audio data; a right front speaker 230R positioned at the right front to the audience; a left front speaker 230L positioned at the left front to the audience; a right rear speaker 230SR positioned at the right rear to the audience; a left rear speaker 230SL positioned at the left rear to the audience; and a speaker for bass mood sound 230LFE for reproducing bass components as bass mood sound corresponding to 0.1 ch. The configurations also can be others such as the one with 6.1 ch in which an additional rear speaker is positioned substantially at the center (namely, substantially opposite to the center speaker 230C and at the rear of the audience), or the one with 7.1 ch in which two additional rear speakers are positioned like surround speakers.

The DAC 210 is connected to the producing device 100, and converts processed digital audio data outputted from the producing device 100 into analog data. The DAC 210 outputs the audio data converted into analog ones to each amplifier 220.

Each amplifier 220 is connected to the DAC 210 and is also connected to the speaker 230. These amplifiers 220 process audio data of analog signals outputted from the DAC 210 so that the data can be outputted from the speaker 230 according to the necessity, and outputs data to the speaker 230 for reproduction.

On the other hand, the producing device 100 comprises a system microcomputer 300, an input operating section 400, a monitor 500, and an audio processor 600. The system microcomputer 300 controls operations of the entire reproducing device 100. To the system microcomputer 300 are connected the input operating section 400, the monitor 500, and the audio processor 600.

The input operating section 400 has a plurality of switches, such as, for example, operation buttons and operation knobs (not shown) with which input operations can be performed. The input operating section 400 outputs a prespecified signal to the system microcomputer 300 in response to operations with these switches to input and set various conditions in the system microcomputer 300. It is to be noted that the description for the input operating section assumes the configuration in which input and setting is conducted by means of input operations with the switches, but the present invention is not limited to this configuration, and any configuration is allowable such as the one in which input operations is conducted through voice input or the like. Further, the configuration also may be the one in which a remote controller is employed so that a signal corresponding to input operations is transmitted via a radio medium to the system microcomputer 300 for inputting and setting various conditions.

In the monitor 500, a liquid crystal, EL (Electro Luminescence) panel or the like is used for a display device. The monitor 500 displays the processing state, reproducing/outputting conditions and contents of input operations of audio data under controls by the system microcomputer 300, and based on a signal outputted from the system microcomputer 300.

The audio processor 600 processes, under controls by the system microcomputer 300, audio data for reproducing and outputting the same as voice from the speakers 230 of the outputting sections 200. The audio processor 600 comprises a plurality of audio data input terminals 610, a DIR (Digital Interface Receiver) 620 as an audio data fetching section, a DSP (Digital Signal Processor) 630 as an audio data processing device, and a plurality (for example, six) of audio data output terminals 660 corresponding to the outputting sections 200.

It is to be noted that description of this embodiment assumes the configuration in which six units, for example, of both the outputting sections 200 and the audio data output terminals 660 are provided so that the number of units of the audio data output terminals 660 corresponds to that of the outputting sections 200, but the configuration also can be the one in which a part of or all of a plurality of the outputting sections 200 are wireless one capable of transferring the processed audio data via a radio medium. With the configuration like this, the reproducing device 100 may be provided with, for example, a transmitting section for transmitting the processed audio data, while the outputting section 200 may be provided with a receiving section for receiving the audio data.

The audio data input terminals 610 include the terminals, to each of which a connector or a lead wire detachably connected to a plug (not shown) is connected. The audio data input terminals 610 are detachably connected to an audio data output device for outputting audio data, and the audio data input terminals 610 receives the audio data outputted from this audio data output apparatus. The audio data include, for example, audio data of digital signal converted from audio data of analog signal outputted from an electronic musical instrument (not shown) with an analog/digital converter, or audio data of digital signal read out from a recording medium such as an optical disk and a magnetic disk as described above with a drive of a read-out device.

The DIR 620 is connected to the audio data input terminals 610. The DIR 620 fetches the audio data inputted in the audio data input terminals 610 to convert the data according to the necessity, and outputs the data as an audio data stream to the DSP 630 connected to the DIR 620.

The audio data output terminals 660 include, for example, the terminals, to each of which a connector or a lead wire connected to a plug is connected. The audio data output terminals 660 are connected to the DSP 630 as well as to the DAC 210 of each of the outputting sections 200, and in other words a plurality of the audio data output terminals 660 corresponding to the number of the outputting sections 200 are provided, and the audio data output terminals 660 can be connected to each outputting section 200 via a lead wire. The audio data output terminals 660 then output audio data outputted from the DSP 630 to the outputting section 200.

The DSP 630 is connected to the DIR 620, the audio data output terminals 660, and the system microcomputer 300. The DSP 630 is controlled by the system microcomputer 300, fetches stream audio data outputted from the DIR 620, conducts the so-called mixing processing and effect processing for the audio data according to the necessity, and outputs the audio data to the audio data output terminals 660. The DSP 630 comprises a plurality of input terminals 631 as an audio data fetching section, a data bus 632, a stream data input section 633, a host interface section 634, a memory 635 as a storing section, a computing section 636 as a controlling section as a computing tool, an audio data outputting section 637, and a plurality of output terminals 638.

The input terminals 631 are connected to the DIR 620, and receive an audio data stream outputted from the DIR 620 corresponding to the audio data inputted from each of the audio data input terminals 610. These input terminals 631 are provided in a plurality in number corresponding to the number of the audio data input terminals 610, and receive the corresponding audio data stream inputted in each of the audio data input terminals 610 and then processed in and outputted from the DIR 620

The data stream inputting section 633 is connected to the input terminals 631 and the data bus 632. The data stream inputting section 633 fetches an audio data stream inputted from the DIR 620 to the input terminals 631, and outputs the data to the data bus 632 according to the necessity.

The host interface section 634 is connected to the system microcomputer 300 and the data bus 632. The host interface section 634 outputs instructions and commands from the system microcomputer 300 via the data bus 632 to the computing section 636, and makes the computing section operate according to the necessity.

The audio data outputting section 637 is connected to the data bus 632 and the output terminals 638. The audio data outputting section 637 fetches the audio data processed as described below in the computing section 636 from the data bus 632, and outputs the data to the output terminals 638 according to the necessity.

The output terminals 638 are provided in a plurality in number corresponding to the number of the input terminals 631. These output terminals 638 output the audio data stream inputted in the input terminals 631 and then outputted from the audio data outputting section 637 as audio data L, R, LS, RS, C and LFE (Low Frequency Effect) for each channel reproduced and outputted from the speaker 230 of each outputting section 200. It is to be noted that the audio data LFE corresponds to 0.1 ch of 5.1 ch, namely, is a channel containing only bass components which are bass mood sound reproduced and outputted from the speaker 230 LFE for base mood sound, while in turn, though details are described later, the speaker 230 LFE for base mood sound can also function as a channel, with a switching operation, for reproducing and outputting audio data as it is, without filtering off sound at a prespecified frequency, like other speakers 230C, 230F, 230L, 230SR and 230SL.

The memory 635 has the configuration, for example, in which a recording medium such as an optical disk and a magnetic disk or a memory card comprises a drive or a driver for recording and reading out various data, and in which a recording medium is a semiconductor chip capable of storing and reading out various data. The memory 635 is connected to the data bus 632 and stores therein programs for processing audio data streams according to the necessity, processing conditions for deference of prespecified stream audio data, and the like. The memory 635 also has, for example, a data storage area 635A for storing therein an audio data stream as described later.

The computing section 636 is connected to the data bus 632, and processes stream audio data outputted from the stream data input section 633 to the data bus 632 based on the programs and processing conditions stored in the memory 635 in response to a command signal from the system microcomputer 300 according to the necessity.

The DSP 630 is composed of, as shown in FIG. 2, a controller 710 functioning as a controlling section, the data storage area 635A of the memory 635, and a mixing effect section 720. Namely, the controller 710 temporarily stores in the data storage area 635A an audio data stream inputted from each input terminal 631, and also makes the mixing effect section 720 assign the data to each speaker 230. The mixing effect section 720 comprises, as shown in FIG. 3, a plurality of, namely, the number of units corresponding to the input terminals 631 of the audio data processing sections 800. These audio data processing sections 800 comprise an output adjusting section 810, an effect processing section 820, a plurality of low-pass filters 830, a filter selecting section 840, a plurality of discrete output adjusting sections 850, a delay processor 860, and a bass sound processing switching section 870.

The controller 710 is connected to the memory section 635 as well as to the input terminal 631, and is connected also to the delay processor 860, filter selecting section 840, and bass sound processing switching section 870 in each audio data processing section 800 of the mixing effect section 720. The controller 710 fetches a synchronization signal inputted into any of the input terminals 631, and has audio data streams inputted to other input terminals 631 temporally stored in a data storage area 635A of the memory section 635 based on this synchronization signal. This synchronization signal is a signal for synchronous output of audio data from the audio data input terminals 610 at the same timing, and includes a reference pulse or an internal clock.

The controller 710 controls, as described in detail below, the delay processing for delaying an audio data stream read out from the data storage area 635A of the memory 635 based on the synchronization signal by controlling the delay processor 860 in each audio data processing section 800. The controls include, for instance, the processing for outputting specified audio data for reproduction based on time information for the specified audio data, when a specified image is outputted, in synchronism to output of the image, and the processing for synchronously outputting audio data streams inputted from the audio data input terminals 610 respectively based on the time information included in the audio data streams.

Further the controller 710 executes the processing for having an audio data stream outputted from the effect processing section 820 passed through the specified low-pass filter 830 by controlling the filter selecting section 840 of each audio data processing section 800. The controller 710 also executes the processing, as described in detail below, for deciding whether the audio data stream outputted from the effect processing section 820 is to be ordinarily outputted for reproduction from the specified speaker 230 or to be outputted for reproduction as specified bass mood sounds by controlling the bass sound processing switching section 870.

Controls by the system controller 710 over the filter selecting section 840 and the bass sound processing switching section 870 in each audio data processing section 800 are carried out, for instance, according to specified control signals which the system microcomputer 300 outputs based on signals outputted in input operations with operation buttons or operation knobs in the input operating section 400 and in response to input operations from the speakers 230. The computing section recognizes the control signals outputted from the system microcomputer 300 via the host interface section 634 and the data bus 632, and the controller 710 as a program provides controls for switching based on the control signals.

The output adjusting sections 810 of the audio data processing sections 800 in the mixing effect section 720 are connected to the input terminals 631 respectively to fetch audio data streams inputted to the input terminals 631, and provide controls for outputting the fetched audio data streams at specified output levels respectively. The output controls include, for instance, output of a control signal from the system microcomputer 300 for adjusting an output level, namely a volume of audio data from the speaker 230 in response to an input operation based on signals outputted corresponding to the input operations with operation buttons or operation knobs in the input operating section 400. The control signal outputted from the system microcomputer 300 is recognized by the computing section 636 via the host interface section 634 and the data bus 732, and the output adjusting section 810 as a program controls an output level for the fetched audio data stream in response to the control signal.

The effect processing section 820 is connected to the output adjusting section 810, and subjects an audio data stream outputted from the output adjusting section 810 to the effect processing. More specifically, the effect processing section 820 changes the sound quality of audio data streams reproduced and outputted from the speakers 230 by changing tone or adding echo thereto (or the like) through changing the frequency or phase. In the effect processing section 820, contents of the effect processing is set, for instance, based on a control signal from the system microcomputer 300 in response to an input operation in the input operating section 400 as described above. The effect processing section 820 divides the audio data streams having been subjected to the effect processing to a plurality of smaller streams and outputs the divided streams. Namely, the delay processor 860 and the filter selecting section 840 are connected to the effect processing section 820, and as described in detail below, the effect processing section 820 divides an audio data stream to six minor data streams in correspondence to the number of speakers 230 outputting the minor data streams respectively, subjects the audio data to the delay processing with the delay processor 860, and can also execute the processing for extracting bass mood sounds with the filter selecting section 840.

The low-pass filter 830 (LPF) filters off data having higher frequencies than a reference frequency in an audio data stream outputted from the effect processing section 820, and allows for passage of data having lower frequencies than the reference frequency therethrough. a plurality of the low-pass filters 830 are provided corresponding to different frequency bands so that data in various different frequency bands can be filtered off thereby. Each of the low-pass filters 820 is connected to the filter selecting section 840.

The filter selecting section 840 is connected to the effect processing section 820, and selects, under control of the controller 710, any one of the low-pass filters 830 to allow for passage of an audio data stream outputted from the effect processing section 820 therethrough. The switching control by the controller 710 is carried out, for instance, according to a control signal from the system microcomputer 300 in response to an input operation in the input operating section 400.

The discrete output adjusting section 850 provides controls over volumes of audio data streams reproduced by the speakers 230 discretely. Also the volume control is carried out, like in the output adjusting section 810, according to a control signal issued from the system microcomputer 300 in response to an input operation in the input operating section 400. The discrete output adjusting section 850 to respond to audio data streams reproduced and outputted from the center speaker 230C, right front speaker 230R, left front speaker 230L, right read speaker 230SR, and left rear speaker 230SL are provided, for instance, between the delay processing section 860 and the effect processing section 820, and the audio data streams divided by and outputted from the effect processing 820 are subjected to the processing for volume control and then to the delay processing. On the other hand, the discrete output adjusting section 850 to respond to audio data streams reproduced and outputted from the speaker 230 LFE for bass mood sounds are provided at positions where the audio data streams are subjected to volume control after the delay processing or the processing by the low-pass filter to filter off data having frequencies in a specified frequency band, namely between the delay processor 860, or low-pass filter 830, and output terminals 638.

The delay processor 860 comprises a plurality of delay processing sections 861 corresponding, for instance, to a number of the output sections 200. Each of the delay processing sections 861 in the delay processors 860 executes the delay processing so that the delay time becomes longer as a distance to the audience becomes shorter with reference to the speaker 230 located at the furthest position from the audience as a reference position in each output section 200. Namely, the delay processing is carried out so that the audience can hear audio data streams from the speakers 230 at the same timing. In relation to the delay processing carried out in relation to positions of the speakers 230, also the configuration in which the delay processing is not carried out by switching is allowable, and therefore the configuration may be employed in which the audio data output terminal 660 is connected not to the output section 200, but to, for instance, an output interface for recording processed audio data in various types of recording media in place of switching operations in the input operating section 400 or in which a transmitting section for transmitting audio data via a network, or an encoder is connected thereto.

The delay processor 860 executes the delay processing under controls by the controller 710 so that the delay time generally becomes relatively longer in response to a switching operation of the filter selecting section 840. Namely, in response to a delay generated when the controller 710 switches the bass sound processing switching section 870 to select the processing for extracting bass sound components from an audio data stream and when the audio data stream is passed through the low-pass filter 830 selected by the controller 710 by switching the filter selecting section 840, audio data streams outputted from other speakers 230 including the center speaker 230C, right front speaker 230R, left front speaker 230L, right rear speaker 230SR, and left rear speaker 230 SL are delayed to synchronize the timing for reproducing and outputting the audio data streams to the timing for reproducing and outputting the bass mood sounds from the speaker 230LFE for bass mood sounds.

More specifically, the delay time is set by the controller 710 so that the group delay characteristics is flat when space-synthesized for reproduction, namely so that the relation between a frequency and a group delay is substantially flat against the frequency when an audio data stream outputted from the speaker 230LFE for bass mood sounds is synthesized with audio data streams outputted from other speakers 230C, 230R, 230L, 230SR, and 230SL, and the delay processing is carried out by each delay processing section 861. In a case where the output sections 200 are connected to the audio data output terminals 660 and also the delay processing to respond to positions of the output sections 200 is required to be executed, the delay processing is carried out by the delay processing sections 861 based on signals generated by adding delay times relating to the distances to the audience to the preset delay time.

When the low-pass filter 830 is a Butterworth type of low-pass filter comprising a ladder-formed LC circuit, the delay time is computed according to the cut-off frequency, which is a frequency for cutting off, and the number of the low-pass filters, namely a number of reactors and capacitors connected to the ladder-formed LC circuit, in the matrix form as shown in Table 3 below based on the Butterworth characteristics. The controller 710 computes the delay time through the operational expression for computing the delay time.

Also the configuration is allowable in which a result of computing is stored in the memory section 635 as data having a matrix-formed tabular structure indicating the cut-off frequencies and a number of low-pass filters 830 as shown in Table 3, and a delay time corresponding to the selected low-pass filter 830 is read out from the matrix-formed tabular structure data shown in Table 3.

TABLE 3

| | |
|---|---|
| Cut-off | Number of PLF |

| frequency | 1 | 2 | 3 | 4 | 6 | 8 |
|---|---|---|---|---|---|---|
| 63 | 1.1 | 3.6 | 5.7 | 7.7 | 11.6 | 15.2 |
| 80 | 0.9 | 2.9 | 4.6 | 6.1 | 9.1 | 12.1 |
| 100 | 0.7 | 2.2 | 3.6 | 4.9 | 7.2 | 9.6 |
| 125 | 0.6 | 1.7 | 2.9 | 3.9 | 5.7 | 7.6 |
| 160 | 0.4 | 1.4 | 2.2 | 3.1 | 4.4 | 5.9 |

Unit: ms

As the operational expression is used by the controller 710 for computing, for instance, an operational expression approximated with a quadratic function shown in the following mathematic expression (1) may be employed in the range where the cut-off frequency for the Butterworth type of low-pass filter 830 is from 40 Hz to 200 Hz. More specifically, the mathematic expression (1) approximated by the following quadratic expression for a cut-off frequency and the operational expression based on the conditions shown in Table 1 are obtained by obtaining an approximate value by plotting as a function between a cut-off frequency and a number of low-pass filters. In the mathematical expression (1), T indicates a delay time [ms], Fc indicates a cut-off frequency, and a₀, a₁, a₂ indicates coefficients respectively. In a case of the Butterworth type of low-pass filter 830, the values of a₀, a₁, a₂ in the range of cut-off frequency from 40 Hz to 200 Hz are as shown in Table 2.
T=a₀·Fc²+a₁·Fc+a₂ (1)

TABLE 1

| Order | a₀ | a₁ | a₂ |
|---|---|---|---|
| 1 | 4.3E−05 | −0.017 | 1.96 |
| 2 | 2.4E−04 | −0.076 | 7.44 |
| 3 | 3.1E−04 | −0.10 | 10.97 |
| 4 | 4.4E−04 | −0.14 | 14.98 |
| 6 | 6.9E−04 | −0.23 | 22.92 |
| 8 | 8.6E−04 | −0.29 | 29.61 |

The operational expression used by the controller 710 for computing is not limited to the mathematical expression (1) shown in Table 1 above, and the cut-off frequency may be set to values within the range provided by the operational expression shown by the mathematical expression (2) shown below by taking into consideration a tolerance of electrical characteristics in reactors and capacitors each constituting the low-pass filter 830, and a range in which the audience feels that sounds are reproduced from the speakers 230 in the synchronous state. Namely, within the range indicated by the mathematical expression (2), discomfort caused by reproduction and output of bass mood sounds with a delay is not generated, and the audience has the comfortable feeling when hearing the reproduced sounds. The coefficients e₁ and e₂ in the operational expression shown by the mathematical expression (2) are as shown in Table 2 below:
(T−e₁*T)<T<(T−e₂*T) (2)

TABLE 2

| Order | e₁ | e₂ |
|---|---|---|
| 1 | 0.10 | 0.15 |
| 2 | 0.10 | 0.15 |
| 3 | 0.10 | 0.15 |
| 4 | 0.10 | 0.15 |
| 6 | 0.10 | 0.10 |
| 8 | 0.10 | 0.10 |

Also in a case where the low-pass filter 830 is not of the Butterworth type, as shown in FIG. 5, assuming that the time point when an amplitude of an impulse response in the low-pass filter 830 is the maximum value is τ, the delay time T can be computed through the operational expression shown by the following mathematical expression (3). Namely by executing the delay processing according to the delay time T, the audience does not feel the discomfort due to reproduction and output of the bass mood sounds with a delay, and feels the comfort when hearing the reproduced sounds.
T=τ+0.15τ (3)

As described above, audio data streams subjected to the delay processing according to the delay computed by the controller 710 and outputted from the delay processor 860 are outputted to the output terminals 638 corresponding to the speakers 230 respectively.

The bass sound processing switching section 870 determines, under controls by the controller 710, whether the audio data reproduced and outputted from the speakers 230 LFE for bass mood sounds is to be outputted as audio data extracted as bass mood sounds by filtering data with specified frequencies by means of passing the data through the low-pass filter 830 or as ordinary audio data with the components having specified frequencies not filtered off like those outputted from other speakers 230C, 230R, 230L, 230SR, and 230SL. Namely the bass sound processing switching section 870 is provided between the delay processing section 861 of the delay processor 860 corresponding to the speaker 230LFE for bass mood sounds or a plurality of low-pas filters 830 and the discrete output adjusting section 850 corresponding to the speaker 230LFE for bass mood sounds. The bass sound processing switching section 870 selects under controls by the controller 710 the delay processing section 861 corresponding to the speaker 230LFE for bass mood sounds or a plurality of low-pass filters 830 to set a quality of sounds reproduced and outputted from the speaker 230LFE for bass mood sounds. The switching control for the bass sound processing switching section 870 by the controller 710 is carried out according a control signal from the system microcomputer 300 issued, for instance, in response to an input operation in the input operating section 400.

[Operations of the Reproducing Device]

Operations for reproduction of audio data by the reproducing device are described below.

(Direct Reproduction Processing)

At first, as a reproducing device's operation for reproduction, the operation for processing input audio data to directly output the audio data from speakers 230 of the output section 200 respectively is described below.

The speakers 230 are provided with prespecified positional relations within a preset allowable range. The speakers are connected to the audio data output terminals 660 of the reproducing device 100, and also an audio data output device such as an electronic musical instrument for outputting audio data or a reader (not shown) is connected to the audio data input terminal 610. When power is supplied to the reproducing device 100 or the audio data output device in this state, system microcomputer 300 recognizes various types of input operations in the input operation section 400 by the audience.

Namely, the computing section 636 recognizes contents of the input operation in the input operating section by the audience to instruct whether the audio data reproduced by the speaker 230 LFE for bass mood sounds is to be outputted as bass mood sounds or similarly from the other speakers 230. The controller 710 switches the bass sound processing switching section 870 according to contents of the input operation. In other words, the bass sounds processing switching section 870 is switched and connected to either the low-pass filter 830 or the delay processor 860 according to a control signal from the controller 710.

The computing section 636 recognizes which of the low-pass filters 830 has been selected and set in correspondence to contents of the setting for bass sounds, namely to the quality of sounds to be reproduced and outputted in the state where the instruction for outputting the audio data as bass mood sounds has been issued. Then, in response to the contents of this input operation, the controller 710 makes the filter selecting section 840 operate for switching to any of the low-pass filters 830.

The computing section 636 recognizes, when the bass sound processing switching section 870 is switched to the low-pass filter 830 for outputting the audio data as bass mood sounds from the speaker 230 LFE for bass mood sounds, the low-pass filter 830 selected by the filter selecting section 840, and computes the delay time for delaying an audio data stream by the delay processor 860. Namely the computing section 636 reads out the delay time corresponding to a range of each of the speakers 230 to the audience previously stored in the memory section 635. Further the computing section 636 reads out the delay time corresponding to a delay time generated when the audio data stream passes through the low-pass filter 830 in correspondence to the characteristics of the selected low-pass filter 830 from data previously stored with a matrix-like tabular structure as shown in Table 1. Then the computing section 636 sums up the delay times read out as described above and sets the total delay time so that the delay processing can be carried out by the delay processing section 861 in each delay processor 860.

In addition to the configuration in which a delay time is read out from the data stored in the memory section 635, in a case where an operational expression shown by the mathematical expression (1) or the mathematical expression (3) is stored in the memory section 635, a delay time generated when an audio data stream passes through the low-pass filter 830 is computed through the operational expressions. The delay processing may be carried out by adding the delay time computed as described above to the delay time corresponding to a distance of each speaker from the audience.

Further the computing section 636 recognized an output level for reproducing the audio data from each of the speakers 230, namely contents of an input operation for a volume of output sounds. Then, based on the contents of the input operation, the controller 710 sets conditions, namely sets prespecified values for volume control in the output adjusting section 810 and in discrete output adjusting section 850 so that the output level for reproducing the audio data stream passing therethrough can be adjusted.

Further the computing section 636 sets a quality of audio data to be reproduced from each of the speakers 230, namely recognizes contents of an input operation for setting the processing for sound effect. Then, based on the recognized contents of the input operation, the controller 710 sets values for subjecting the audio data to the prespecified sound effect processing by controlling the sound effect processing section 820 so that the passing audio data stream can be subjected to the sound effect processing corresponding to the contents of the input operation.

In this state, when the audio data is outputted from an audio data output device, the audio data is inputted into the audio data input terminal 610 of the reproducing device 100 to which the audio data output device is connected. The audio data inputted into each audio data input terminal 610 is subjected to necessary conversion in the DIR 620, and is outputted as an audio data stream to each DSP 630. In the DPS 630, a plurality of audio data streams fetched by the audio data input terminals 610 are fetched by a plurality of input terminals 631 corresponding to the audio data input terminals 610 respectively. The audio data streams fetched by the input terminals 631 are subjected to processing by the audio data processing sections 800 in the mixing effect section 720 respectively.

Namely, the audio data streams inputted into the input terminals 631 are subjected to the processing for output level adjustment by the output adjusting section 810, namely for controlling the volumes according to the contents previously set based on control signals from the controller 710 corresponding to an input operation by the audience in the input operation section 400. Further the audio data streams having been subjected to the processing for volume control are subjects to the sound effect processing by the sound effect processing section 820, namely converted to prespecified sound qualities according to the contents of the input operation in the input operation section 400.

As the filter selecting section 840 and the bass sound processing section/switching 870 are connected to the low-pass filter 830, the audio data streams outputted from the sound effects processing section 820 pass through the low-pass filter 830 selected by the filter selecting section 840. When the audio data streams pass through the low-pass filter 830, frequency components in the audio data streams higher than the preset cut-off frequency are removed from the audio data streams, and then the audio data streams are outputted to the discrete output adjustment sections 850 connected in the downstream side and corresponding to the speakers 230 LFE for bass mood sounds. The audio data streams outputted to the discrete output adjusting sections 850 are subjected to the processing for volume control according to the preset contents corresponding to an input operation in the input operating section 400 and then are outputted to the output terminals 638, and are combined with data streams outputted from other audio data processing sections 800.

The audio data streams having passed through the sound effect processing section 820 are subjected to the processing for volume control by the discrete output adjusting sections 850 corresponding to the speakers 230C, 230R, 230L, 230SR, and 230SL according to the preset contents corresponding to an input operation in the input operating section 400, and are outputted to the delay processor 860. The audio data streams outputted to the delay processor 860 are subjected to the delay processing by the delay processing section 861 corresponding to the speakers 230C, 230R, 230L, 230SR, and 230SL according to the delay time previously set for the low-pass filter 830, outputted to the output terminals 638 connected to the corresponding speakers 230C, 230R, 230L, 230SR, and 230SL, and are combined with the audio data streams having been subjected to the delay processing and outputted from the audio data processing sections 800.

The audio data streams combined in the output terminals 638 with those from the audio data processing sections 800 to be outputted from the output sections 200 respectively are outputted from the audio data output terminals 660 to DACs 210 of the output sections 200, and are converted to analog signal audio data streams according to the necessity. Further the audio data streams are amplified by the amplifiers 220 and are reproduced from the speakers 230.

When it is determined by the computing section 636 based on the recognition of an input operation performed, for instance, when power is turned that the bass mood sounds are not necessary, the controller 710 simply reads out the delay times corresponding to positions of the speakers 230 from the memory section 635 and set the values in the delay processor 860. The determination that bass mood sounds are not necessary is made when it is recognized that the bass sound processing switching section 870 has been switched and connected to the delay processor 860 instructing output of audio data not having been subjected to the processing for cutting off audio data at a prespecified frequency like those outputted from other speakers 230 also from the bass sound speakers 230LFE.

In this case, the audio data streams outputted from the sound effect processing 820 are sent via the discrete output adjusting sections 850, or without being subjected to any specific processing to the delay processor 860, because the bass sound processing switching section 870 is connected to the delay processor 860, and do not pass through the low-pass filter 830. Then the audio data streams are subjected to the delay processing by the delay processing section 861 in the delay processor 860 according to the delay times corresponding to positions of the speakers 230 and are sent to the output terminals 638, while the audio data streams having been subjected to the delay processing according to the delay time corresponding to a position of the bass sound speaker 230 LFE are sent via the discrete output adjusting sections 850 to the output terminals 638 and are combined with other audio data streams respectively, and are sent to the DACs 210 of the output sections 200.

(Processing for Reproducing Accumulated Data)

Operations of the reproducing device 100 for once storing input audio data and outputting the stored audio data in synchronism from the speakers 230 for reproduction thereof are described below.

When power to the reproducing device 100 or the audio output device is turned on after all the necessary connections have been established, like in the case described above, the system microcomputer 300 recognized various input operations in the input operating section 400 by the audience. Further the computing section 636 waits for input or an instruction for storing input audio data in response to an input operation in the input operating section 400.

When the audio data is outputted from the output device and is inputted into the audio data input terminal 610 of the reproducing device 100, and audio data is subjected to the processing by the mixing effect section 720 and is outputted from the speakers 230 for reproduction. While the audio data is being inputted from the audio data input terminal 610, when the computing section 636 recognizes an instruction for storing the audio data in response to an input operation by the input operating section 400, the controller 710 stores the audio data stream in a data storage area 635A of the memory section 635 with the time information as timing information for a period of time from a point of time when storage of the audio data is started according to the synchronization signal until a point of time for termination of the operation for storing the audio data added thereto.

The plurality of sets of audio data stored in the memory section 635 as described above are displayed as output levels being plotted using the horizontal axis for the time and the vertical axis for the output level on a display unit (not shown) connected, for instance, to the reproducing device 100. When the controller 710 executes various types of processing such as jointing or overlaying the displayed audio data according to the necessity in response to an input operation in the input operating section 400 and then outputs the audio data in the processed state, the controller 710 reads out the audio data stream from the data storage area 635A of the memory section 635 based on the time information added to each audio data stream in response to the display. The controller 710 further subjects the read audio data streams to the delay processing as described above, output to the output terminals 638 for combining the audio data streams with other audio data streams, and outputs the combined audio data streams from the speakers 230 of the respective output sections 200 in the state processed on the display unit.

(Audio Data Recording)

Next, the operations of the reproducing device 100 when, for instance, an output interface is connected thereto for recording processed audio data in a recording medium or distributing the audio data through a network in place of the output section 200 is described below.

After all of the necessary connections are established, when power to the reproducing device 100 or the audio data output device is turned on, like in the case described above, the system microcomputer 300 recognized various input operations by an operator in the input operating section 400. When it is recognized that an input operation instructing an operation for recording the processed audio data or distributing the audio data through a network is carried out, the controller 710 provide controls, as the delay processing in the delay processors 860, to indicate that it is not necessary to take into consideration the delay processing for a position of each of the speakers 230.

When the audio data is inputted, if it is necessary to pass the audio data through the low-pass filter 830 as described above, a prespecified delay time is read out or computed, the audio data is subjected to the delay processing according to the delay time read out or computed as described above and is outputted to the output terminal 638 to be combined with other audio data and then to the output interface connected to the audio data output terminal 660.

(Effects and Advantages of the Reproducing Device)

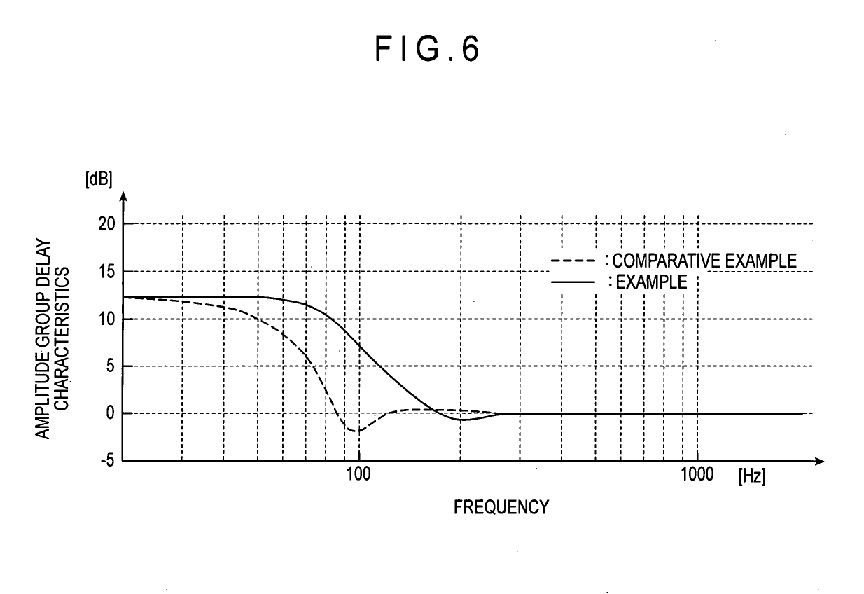

A result of experiment for a case in which the delay processing is executed and a case in which the delay processing is not executed when passing audio data through the low-pass filter 830 in the embodiment described above is described below. FIG. 6 is a graph showing a difference between the cases with and without the delaying processing in the relation to the frequency amplitude characteristic and frequencies in the embodiment.

The embodiment described above in which the delay processing is executed and a comparative example in which the delay processing is carried out taking into consideration only a distance between the audience and each speaker were compared to each other for the group delay characteristics under the conditions that the Butterworth type of low-pass filter was used as the low-pass filter 830 and the audio data was passed through the low-pass filter 830 with the attenuation as shown in FIG. 6. A result of the comparison is shown in FIG. 4. From FIG. 4, it is understood that, by subjecting the audio data to the delay processing in the same way as that employed in the embodiment taking into consideration the characteristics of the low-pass filter 830, the group delay characteristics become substantially flat, and reproduction of the audio data is executed in the excellent state.

As described above, in the embodiment described above, the controller 710 subjects the audio data outputted from the speakers 230C, 230R, 230L, 230SE, and 230SL for reproduction without being passed through the low-pass filter 830 to the delay processing in each delay processing section 861 in the delay processor according to the delay time which is a delay generated when the audio data is passed through the low-pass filter allowing for passage of audio data having specified frequencies to be outputted from the specified speaker 230LFE. Because of the configuration as described above, even when bass components are extracted from the audio data for reproduction and a delay is generated in the timing for reproduction as compared to other audio data because of the processing for passing the audio data through the low-pass filter 830, other audio data is delayed according to the delay and can be outputted at the same timing as that for the bass components for reproduction. Therefore, even if the bass components to be extracted are switched by a plurality of low-pass filters 830, correct timing for reproduction can be obtained each time, which enables reproduction of excellent audio data.

Then the controller 710 computes the delay time based on the operational expression expressed by the mathematical expression (1) providing an approximate value through a function for computing a delay time minimizing dispersion of the group delay characteristics in the low-pass filter 830, which the audio data passes through, for each frequency. Because of this configuration, the delay time for reproducing both audio data for bass components passing through the low-pass filter 830 and other audio data not passing through the low-pass filter 830 at the same timing can easily be obtained in response to the characteristics of the low-pass filter 830.

Further the controller 710 computes the delay time based on a quadratic function for a cut-off frequency to be filtered off by the low-pass filter 830. Because of this feature, the controller 710 can easily compute the delay time for reproduction of audio data in the excellent state at the same timing with the processing load reduced, so that the processing can be executed at a high speed with the configuration easily simplified, which enables easy reproduction of audio data in the excellent state. In addition, it is not necessary to store audio data in the matrix state in the memory section 635 in correspondence to a plurality of low-pass filters 830, so that a memory space in the memory section 635 can efficiently be utilized and the configuration can easily be simplified. Further the delay times previously computed through the operational expression are stored with the data structure correlated in the matrix state to the low-pass filters 830 which the audio data is passed through and are read out according to the necessity, so that the time until acquisition of a delay time is not necessary and the audio data can be processed quickly, so that the time until reproduction of audio data can be shortened and the audio data is reproduced in the excellent state.

Further the controller 710 computes the delay time through the mathematical expression (1) in which, assuming that T [ms] indicates a delay time and Fc indicates the cut-off frequency, the coefficients a₀, a₁, and a₂ are the values as shown in Table 1. Because of this feature, the group delay characteristics for a frequency can easily be flattened, so that the audio data can be reproduced at the same timing in the excellent state by using the simple operational expression. Especially, by using the Butterworth type of low-pass filter widely used as the low-pass filter 830, audio data can be reproduced in the excellent state, and further the audio data can be reproduced in the more excellent state by using a low-pass filter with the cut-off frequency in the range from 40 Hz to 200 Hz.

Further the controller 710 executes the delay processing according to the delay time computed through the mathematical expression (2) in which the coefficients e₁ and e₂ are the values shown in Table 2. Because of the feature, even when the Butterworth type of low-pass filter is not used, audio data can be reproduced in the excellent state with the versatility further improved.

Further, assuming that the time when amplitude of an impulse response in the low-pass filter 830 becomes the maximum value is τ, the controller 710 executes the delay processing by computing the delay time T through the mathematical expression (3). This configuration is applicable not only to the Butterworth type of low-pass filter 830, but also to any type of low-pass filters including the Chebycheff type of low-pass filter, an oval type of low-pass filter, and Bessel type of low-pass filter, and the versatility is improved.

Further switching by the bass sound processing switching section 870 is possible between a case where audio data is passed through the low-pass filter 830 and a case where the audio data is not passed through the low-pass filter 830, so that the speaker 230LFE for bass mood sounds can be used for ordinary audio data like other ordinary speakers 230C, 230R, 230L, 230SR, and 230 SL, so that the versatility can further be improved.

[Variants of the Embodiment]

The present invention is not limited to the embodiment described above, and the following variants within a range in which the objects of the present invention can be achieved are encompassed within a scope of the present invention.

In the embodiment described above, a number of channels are not limited five as described above, and the configuration is allowable in which multi-channel audio data for two or more channels is reproduced by using two or more speakers 230. Further the configuration is allowable in which also image data is processed for displaying the image data on a display unit. In the configuration for processing also image data, it is required to subject also the image data to the delaying processing according to a delay generated when the data is passed through the low-pass filter 830. With this configuration, the image data can be reproduced in synchronism to the audio data reproduced from the speakers 230, so that the audience can enjoy both the audio and image data in the excellent state.

The description above assumes the configuration in which the audio data inputted from the audio data input terminal 610 are those from a musical instrument or a reader, but also the configuration is allowable in which audio data to be distributed through a network is inputted.

The reproducing device 100 is not limited to an audio device, and also the configuration is allowable in which, for instance, the reproducing device 100 reads out a program and reproduces audio data according to the program, in which a plurality of personal computers or computers are connected to each other for forming a computing section as the DSP 630, or in which a circuit board with semiconductor chips or a plurality of electric parts mounted thereon is employed. Further the configuration is allowable in the present invention in which a program read out by the computer(s) and a recording medium with the program recorded therein are used. In this case, extension of the applications can easily be realized.

Although the description above assumes the configuration in which a plurality of low-pass filters 830 are provided and are switched by the filter selecting section 840, also the configuration is allowable in which only one low-pass filter 830 is used and switching of the low-pass filter 830 is not performed.

Further, although the description above assumes the configuration in which the audio data is not passed through the low-pass filter 830 and the bass processing switching section 870 is provided in the speaker 230 for bass mood sounds to enable switching so that ordinary audio data can be reproduced, also the configuration is allowable in which only the audio data for bass components which is bass mood sound extracted through the low-pass filter 830 can be reproduced.

Although the description of the embodiment above assumes the use of a reproducing device which can execute both the processing for direct reproduction requiring the delay processing and the processing for reproducing accumulated data, also the configuration is allowable in which only either one of the processing is executed. In the processing for reproducing accumulated data, when the audio data is reproduced, the audio data to be passed through the low-pas filter 830 is subjected to the negative delay processing. Namely the configuration is allowable in which the audio data for bass components is extracted from the memory section 635 at a point of time earlier by a period of time equal to a delay time generated when the audio data is passed through the low-pass filter 830 and the audio data is passed through the low-pass filter 830, and at the same time in which the audio data reproduced from the other speakers 230C, 230R, 230L, 230SR, and 230SL is read out from the memory section 635 in synchronism and is subjected to the processing for reproduction without being subjected to the delay processing. Even with the configuration as described above, both the audio data with the bass components extracted for the low-pass filter 830 like in the embodiment described above and the audio data reproduced in the ordinary way can synchronously be reproduced in the excellent state.

The present invention is not limited to the variants of the embodiment described above, and other various variants are possible within a scope of the present invention.

(Advantages of the Embodiment)

In the embodiment described above, the controller 710 subjects the audio data outputted from the speakers 230C, 230R, 230L, 230SR, and 230SL for reproduction without being passed through the low-pass filter 830 to the delay processing by the delay processor 860 according to the delay time generated when the audio data outputted from the specified speaker 230 LFE is passed through the low-pass filter allowing passage of audio data having a specified frequency. Because of the feature, when bass components are extracted from the audio data for reproduction by passing through the low-pass filters 830, even the timing for reproducing the audio data is delayed from the timing for reproducing other audio data, the other audio data can be delayed according to the delay of the bass components so as to be outputted for reproduction at the same timing as that for the bass components. Therefore, even when the bass components to be extracted by a plurality of low-pass filters 830 are switched, the correct timing for reproduction can be obtained each time, so that the audio data can be reproduced in the excellent state.

Further in the embodiment described above, the controller 710 has audio data stored in the memory 635 together with time information as timing information concerning the timing when the audio data is fetched. Then the audio data correlated to the time information for a timing earlier by a period of time equal to a delay generated when the audio data outputted from the specified speaker 230 LFE is read out from the memory section 635 based on a synchronization signal with the audio data passed through the low-pass filter 830 and outputted from the speaker 230 LFE for reproduction, and at the same time the audio data correlated to the time information for a timing corresponding to the synchronization signal is read out from the memory 635, and is outputted from the speakers 230C, 230R, 230L, 230SR, and 230SL for reproduction without being passed through the low-pass filter 830. Because of this configuration, even when the timing is delayed from the timing for reproducing other audio data because of the processing for extracting bass components from the audio data and passing the audio data through the low-pass filter 830, the audio data is read out at a timing earlier than that for other audio data for synchronization, so that the audio data can be outputted for reproduction at the same timing as that for the other data. Because of this configuration, even when the bass components extracted by a plurality of low-pass filters 830 are switched, the correct timing for reproduction can be obtained each time, and the audio data can be reproduced in the excellent state.

1. An audio data processing device for processing audio data so that the audio data can be reproduced from a plurality of speakers, said audio data processing device comprising:
an audio data fetching section for fetching said audio data;
a delay processor for delaying said audio data;
a filter only allowing passage of audio data having a prespecified frequency outputted from said prespecified speakers; and
a control section for subjecting the audio data reproduced by said speakers without passing through said filter to the delay processing by the delay processor to delay the audio data by the period of time corresponding to the delay generated when said audio data passes through said filter.

2. The audio data processing device according to claim 1 having a plurality of said filters allowing passage of audio data at different frequencies respectively, said audio processing device further comprising:
a filter selecting section for selecting any of these filters allowing passage of said audio data,
wherein said control section subjects the audio data reproduced by said speakers without passing through the filter to the delay processing to delay the audio data by the period of time corresponding to the delay generated when said audio data passes through the filter.

3. The audio data processing device according to claim 1,
wherein said control section executes the delay processing by computing a delay time for delaying the audio data by the replay processor based on a function providing an approximate value of a value at which the dispersion of group delay characteristics of the filters, which pass the audio data, for each frequency is minimized.

4. The audio data processing device according to claim 1 comprising:
a storage section for storing therein a delay time for delaying the audio data by said relaying section based on the function providing an approximate value of a value at which the dispersion of group delay characteristics of the filters, which pass the audio data, for each frequency is minimized,
wherein said control section subjects the audio data to the replay processing by said replay processor by reading out the delay time corresponding to the filter with the audio data passing therethrough from said storage section.

5. The audio data processing device according to claim 3,
wherein said function is a quadratic function for a cut-off frequency filtered off by said filter.

6. The audio data processing device according to claim 5,
wherein, assuming that T indicates the delay time and Fc indicates the cut-off frequency, the function is the following expression (1):
T=a₀*Fc²+a₁·Fc+a₂ (1)
and in the expression, the coefficient a₀, a₁, and a₂ are the values shown in Table 1 below:
TABLE 1

| Order | a₀ | a₁ | a₂ |
|---|---|---|---|
| 1 | 4.3E−05 | −0.017 | 1.96 |
| 2 | 2.4E−04 | −0.076 | 7.44 |
| 3 | 3.1E−04 | −0.10 | 10.97 |
| 4 | 4.4E−04 | −0.14 | 14.98 |
| 6 | 6.9E−04 | −0.23 | 22.92 |
| 8 | 8.6E−04 | −0.29 | 29.61 |

7. The audio data processing device according to claim 6,
wherein said control section makes said delay processor execute the delay processing based on a delay time T computed based on the following expression (2):
(T−eᵢ*T)<T<(T−e₂*T) (2)
and in the expression, the coefficients e₁ and e₂ are the values shown in Table 2 below:
TABLE 2

| Order | e₁ | e₂ |
|---|---|---|
| 1 | 0.10 | 0.15 |
| 2 | 0.10 | 0.15 |
| 3 | 0.10 | 0.15 |
| 4 | 0.10 | 0.15 |
| 6 | 0.10 | 0.10 |
| 8 | 0.10 | 0.10 |

8. The audio data processing device according to claim 1,
wherein said filter is the Butterworth type of low-pass filter with the cut-off frequency in the range from 40 Hz to 200 Hz.

9. The audio processing device according to claim 1,
wherein, assuming that the time when an amplitude of an impulse response in said filter is the maximum value is τ, said control section delays the audio data by τ+0.15τ.

10. The audio data processing device according to claim 1 further comprising:
a storage section for storing therein said fetched audio data together with timing information concerning the timing when the audio data is fetched,
wherein, based on the timing information, said control section has the audio data to be passed through said filter, which is stored in said storage section, be read out and passed through said filter earlier by the period of time corresponding to the delay generated when the filter is passed through said filter.

11. The audio data processing device according to claim 10,
wherein said delay processor reproduces the audio data not passing through said filter from each said speaker without subjecting the audio data to the delay processing.

12. The audio data processing device according to claim 10,
wherein said control section fetches a synchronization signal corresponding to the timing when said audio data is fetched and reads out the audio data stored in said storage section based on the synchronization signal.

13. An audio data processing device for processing audio data so that the audio data can be reproduced from a plurality of speakers, said audio data processing device comprising:
an audio data fetching section for fetching said audio data;
a storage section for storing therein said fetched audio data together with the timing information concerning the timing when the audio data is fetched;
a filter allowing for passage of data having a prespecified frequency among said audio data outputted from said prespecified speakers; and
a control section for fetching a synchronization signal corresponding to the timing when said audio data is fetched, reading out, based on the synchronization signal, said audio data stored in said storage section and correlated to said timing information specifying an earlier timing corresponding to a delay generated when said audio data passes through said filter and having the audio data passed through said filter so that the audio data can be outputted to be reproduced from said speakers, and also having said audio data stored in said storage section and correlated to said timing information specifying a timing corresponding to said synchronization signal outputted without being passed through said filter so that the audio data can be outputted to be reproduced by said speakers.

14. An audio data processing method of processing audio data so that the audio data can be reproduced from a plurality of speakers, comprising the steps of:
having the audio data outputted from said prespecified speakers to pass through a filter allowing passage of audio data having a prespecified frequency; and
subjecting the audio data not passing through said filter and reproduced by said speakers to the delay processing for delaying the audio data by the delay generated when said audio data passes through said filter.

15. An audio data processing method for processing audio data so that the audio data can be reproduced from a plurality of speakers, comprising the steps of:
fetching said audio data and also fetching a synchronization signal corresponding to the timing when the audio data is fetched;
storing the fetched audio data together with timing information concerning the timing when the audio data is fetched based on said synchronization signal; and
reading out, based on the synchronization signal, said audio data correlated to said timing information for an earlier timing corresponding to the delay generated when said audio data outputted from said speakers is passed through a filter allowing passage of the audio data having a prespecified frequency to pass the audio data through said filter so that the audio data can be outputted to be reproduced from said speakers, and also reading out the audio data correlated to said timing information for a timing corresponding to said synchronization signal and outputting the audio data so that the audio data can be reproduced from said speakers without being passed through said filter.

16. An audio data processing program for making a computing section execute an audio data processing method for processing audio data so that the audio data can be reproduced from a plurality of speakers, the method comprising the steps of:
having the audio data outputted from said prespecified speakers to pass through a filter allowing passage of audio data having a prespecified frequency; and
subjecting the audio data not passing through said filter and reproduced by said speakers to the delay processing for delaying the audio data by the delay generated when said audio data passes through said filter.

17. An audio data processing program for making a computing section execute an audio data processing method for processing audio data so that the audio data can be reproduced from a plurality of speakers, the method comprising the steps of:
fetching said audio data and also fetching a synchronization signal corresponding to the timing when the audio data is fetched;
storing the fetched audio data together with timing information concerning the timing when the audio data is fetched based on said synchronization signal; and
reading out, based on the synchronization signal, said audio data correlated to said timing information for an earlier timing corresponding to the delay generated when said audio data outputted from said speakers is passed through a filter allowing passage of the audio data having a prespecified frequency to pass the audio data through said filter so that the audio data can be outputted to be reproduced from said speakers, and also reading out the audio data correlated to said timing information for a timing corresponding to said synchronization signal and outputting the audio data so that the audio data can be reproduced from said speakers without being passed through said filter.

18. A recording medium with an audio data processing program recorded therein so that the program can be read out by a computing section, wherein the audio data processing program makes the computing section execute an audio data processing method for processing audio data so that the audio data can be reproduced from a plurality of speakers, the method comprising the steps of:
having the audio data outputted from said prespecified speakers to pass through a filter allowing passage of audio data having a prespecified frequency; and
subjecting the audio data not passing through said filter and reproduced by said speakers to the delay processing for delaying the audio data by the delay generated when said audio data passes through said filter.

19. A recording medium with an audio data processing program recorded therein so that the program can be read out by a computing section, wherein the audio data processing program makes the computing section execute an audio data processing method for processing audio data so that the audio data can be reproduced from a plurality of speakers, the method comprising the steps of:
fetching said audio data and also fetching a synchronization signal corresponding to the timing when the audio data is fetched;
storing the fetched audio data together with timing information concerning the timing when the audio data is fetched based on said synchronization signal; and
reading out, based on the synchronization signal, said audio data correlated to said timing information for an earlier timing corresponding to the delay generated when said audio data outputted from said speakers is passed through a filter allowing passage of the audio data having a prespecified frequency to pass the audio data through said filter so that the audio data can be outputted to be reproduced from said speakers, and also reading out the audio data correlated to said timing information for a timing corresponding to said synchronization signal and outputting the audio data so that the audio data can be reproduced from said speakers without being passed through said filter.
